(19) United States
(12) Patent Application Publication
(10) Pub. No.: US 2013/0107616 A1
(43) Pub. Date: May 2, 2013

(54) MAGNETORESISTIVE EFFECT ELEMENT AND RANDOM ACCESS MEMORY USING SAME

(71) Applicants: Hideo Ohno, Sendai (JP); Shoji Ikeda, Sendai (JP); Hiroyuki Yamamoto, Shiki (JP); Kenchi Ito, Kunitachi (JP); Hiromasa Takahashi, Hachioji (JP)

(72) Inventors: Hideo Ohno, Sendai (JP); Shoji Ikeda, Sendai (JP); Hiroyuki Yamamoto, Shiki (JP); Kenchi Ito, Kunitachi (JP); Hiromasa Takahashi, Hachioji (JP)

(21) Appl. No.: 13/808,967

(22) PCT Filed: Jul. 9, 2010
(86) PCT No.: PCT/JP2010/061669

§ 371 Date: Jan. 8, 2013

(51) Int. Cl. H01L 29/82

(52) U.S. Cl. CPC H01L 29/82; G11C 11/1675
USPC 365/158; 257/421

(57) ABSTRACT

A magnetoresistive effect element is provided that exhibits a low writing current density while maintaining a high TMR ratio. A laminated structure of a second ferromagnetic layer/a non-magnetic layer/a first ferromagnetic layer is employed as a recording layer. A material of bcc crystalline structure, such as CoFeB, is employed as a second ferromagnetic layer being in contact with MgO barrier layer. A material whose anisotropy field Hk_{⊥} in the perpendicular direction is large and that satisfies the relationship of 2πrMₛ<H_{k⊥}<4πMₛ is employed as a first ferromagnetic layer. Although a magnetic easy axis of the first ferromagnetic layer lies in-plane, it has a high perpendicular anisotropy field of half or more of the demagnetizing field in the perpendicular direction. Therefore, the effective demagnetizing field in the perpendicular direction is reduced, and a writing current density can be reduced. Further, a high TMR ratio can be maintained because a material of a bcc crystalline structure comes in contact with the MgO barrier layer.

### TECHNICAL FIELD

The present invention relates to a magnetoresistive effect element using an in-plane magnetization material and a random access memory using same.

### BACKGROUND ART

In recent years, Magnetic Random Access Memory (MRAM) has been developed as a memory using a magnetic material. The MRAM uses Magnetic Tunneling Junction (MTJ) utilizing a Tunneling Magnetoresistive (TMR) effect as a factor element. The MTJ element has a structure in which a non-magnetic layer (insulating layer) is disposed between two ferromagnetic layers (recording layer and pinned layer), and the magnetization direction of one side of the ferromagnetic layers (recording layer) can be reversed by an external magnetic field. MTJ elements record information in this way, by controlling magnetization direction of a magnetic layer. Since the magnetization direction of a magnetic material does not change even when power supply is turned off, it is possible to realize a non-volatile operation in which recorded information is maintained. As a scheme in which information is rewritten by changing the magnetization direction of an MTJ element, in recent years, a spin transfer torque magnetization reversal (spin injection magnetization reversal) scheme has been found in which magnetization is reversed by directly flowing a direct current to the MTJ element, in addition to a scheme in which a magnetic field is applied externally. For example, Patent Literature 1 discloses an MTJ element using an in-plane magnetization material as a recording layer and utilizes spin injection magnetization reversal and a memory in which the MTJ element is integrated (called Spin-transfer torque Magnetic Random Access Memory: SPRAM, or STT-MRAM).

In an MTJ element, resistance of the element varies according to the difference between the respective magnetization directions of the recording layer and the pinned layer. The ratio of resistance change is called a Tunnel Magnetoresistance (TMR) ratio and a high TMR ratio is desired in memory applications in order to read information of “0” and “1” without any error. In order to yield a high TMR ratio, a crystalline orientation control of the barrier layer and the high polarizability magnetic layers on both sides thereof is important. From the past researches on in-plane magnetized TMR devices, it is known that a high TMR ratio can be obtained when MgO (001) having a NaCl structure is used as a barrier layer and a CoFeB layer or a CoFe layer having a bcc (001) crystalline structure is disposed on both sides thereof. When CoFeB is formed thereon under a room temperature, CoFeB grows in an amorphous form. When MgO is formed thereon, MgO (001) crystal grows. After further forming CoFeB thereon, when anneal process is performed, the CoFeB layer is crystal-orientated in bcc (001) with MgO (001) crystal as a nucleus. In the case of in-plane magnetized TMR device, the orientation of MgO (001) and bcc (001) of CoFeB is realized by utilizing such a mechanism.

Also, in SPRAM, a current flows by a transistor connected to an MTJ element, and the magnetization of the recording layer of the MTJ element is reversed. When the gate length of the transistor becomes small in accordance with high integration of a memory, the amount of current that the transistor can flow reduces. Therefore, a lower writing current density J_{c0} is required for an MTJ element employed for an SRPAM. Further, when in advancing miniaturization of elements, thermal stability of magnetic information in the MTJ element becomes a problem. When thermal energy resulting from environmental temperature (k_{B}T; here k_{B} is Boltzmann constant, T is the temperature) becomes higher than magnetic energy barrier (E) necessary for reversing the magnetization direction of the recording layer of the MTJ element, magnetization reversal is caused even without application of an external magnetic field or current. Since the magnetic energy barrier of the MTJ element decreases in accordance with the size reduction, thermal stability factor E/k_{B}T is reduced in accordance with the miniaturization of the element. As stated above, for an MTJ element employed in SPRAM, a high TMR ratio and a high E/k_{B}T, and a low writing current density are required.

In the past, as means for achieving both high E/k_{B}T and low J_{c0}, a recording layer is known as effective that has a synthetic ferri-magnetic structure in which a thin non-magnetic layer is disposed between two ferromagnetic layers and laminated (for example, Non-Patent Literature 1). In this configuration, spin torque is applied to each laminated magnetic layer effectively, and a current required for magnetization reversal reduces as compared to a single layer. Therefore, it becomes possible to increase the volume of the recording layer while maintaining the writing current density J_{c0} that is low as compared to the single layer recording layer and yield a high E/k_{B}T.

The writing current density J_{c0} of an in-plane magnetized MTJ device is represented by the following formula:

$$\begin{matrix}[ Expression 1 ] & \\ {J}_{c 0} = \frac{2 e α {M}_{s} t}{ℏ g ( θ ) P} ( {H}_{k //} + \frac{{H}_{eff}}{2} ) & ( 1 ) \\ {H}_{eff} = {H}_{d} - {H}_{k ⊥} = 4 π {M}_{s} - {H}_{k ⊥} & ( 2 )\end{matrix}$$

Here, e is an elementary charge, Mₛ is saturation magnetization of the recording layer, t is film thickness of the recording layer, α is Gilbert damping factor, h-bar is a value obtained by dividing Planck constant with 2π, g(θ) is an efficiency of the spin transfer torque, θ is angle between the magnetization of the recording layer and magnetization of the pinned layer, P is spin polarizability, H_{k//} is an anisotropy field in the in-plane direction of the recording layer, H_{eff} is an effective demagnetizing field in the perpendicular direction, H_{d} is demagnetizing field in the perpendicular direction of the recording layer, H_{k⊥} is an anisotropy field in the perpendicular direction of the recording layer.

Toward further reduction of J_{c0}, as understood from Formula (1) and Formula (2), reducing Mₛ and H_{eff} is effective. Regarding the former one, for example, Non-Patent Literature 2 discloses an example in which Cr, V, etc. are add to CoFeB of the recording layer to reduce M. Further, regarding H_{eff} reduction of the latter one, Non-Patent Literature 3 discloses an example in which Co/Ni multilayer film is used as the recording layer. Further, Patent Literature 2 discloses an example in which a perpendicularly magnetized magnetic layer is laminated as a capping layer of the in-plane magnetization recording layer.

### CITATION LIST

### Patent Literature

Patent Literature 1: JP 2005-116923 A

Patent Literature 2: JP 2008-28362 A

### Non-Patent Literature

Non-Patent Literature 1: IEEE Transaction on Magnetics, 44, 1962 (2008)

Non-Patent Literature 2: Journal of Applied Physics, 105, 07D 117 (2009)

Non-Patent Literature 3: Applied Physics Letters, 94, 122508 (2009)

### SUMMARY OF INVENTION

### Technical Problem

However, adding Cr or V to CoFeB of the recording layer will cause a problem of lowering the TMR ratio. Further, since Mₛ affects E/k_{B}T, it is difficult to achieve both low J_{c0} and high E/k_{B}T. Further, when Co/Ni multilayer film is used as the recording layer, there arises a problem in which, while J_{c0} is reduced, TMR ratio becomes low since the recording layer does not have the bcc (001) structure. Further, although an effect is shown in which when the perpendicularly magnetized magnetic layer is laminated as the capping layer of the in-plane magnetization recording layer, H_{d} is reduced by stray field from the perpendicularly magnetized magnetic layer, and H_{eff} is lowered, applying a direct current magnetic field in the perpendicular direction to the in-plane magnetization recording layer will tilt the magnetization of the recording layer in the perpendicular direction, resulting in a possibility to decline the TMR ratio and E/k_{B}T.

In view of the foregoing problems, an object of the present invention is to provide an in-plane magnetized MTJ device that maintains a high TMR ratio and a thermal stability factor (E/k_{B}T) while achieving low writing current density J_{c0}.

### Solution to Problem

In the present invention, the recording layer of the in-plane magnetized MTJ device has a laminated structure comprising a second ferromagnetic layer/a non-magnetic layer/a first ferromagnetic layer, a material with a bcc crystalline structure including CoFeB is used for the second ferromagnetic layer being in contact with the barrier layer, and an in-plane magnetization material whose perpendicular magnetic anisotropy magnetic field H_{k⊥} is strong is employed as a first ferromagnetic layer. Regarding writing current density J_{c0}, in order to yield an adequate reduction effect where no perpendicular magnetic anisotropy exists (H_{k⊥}=0, H_{eff}=4πMₛ), it is desirable that H_{eff} of Formula (2) is reduced to half of 4πMₛ(H_{eff}=2πMₛ). In other words, H_{k⊥}>2πMₛ is desirable. However, where H_{k⊥} is larger than the demagnetizing field H_{d}=4πMₛ, the magnetic easy axis is in the perpendicular direction. Therefore, in order to use a first magnetic layer as an in-plane magnetization material, it is necessary that H_{k⊥}<4πM. Therefore, for use as an in-plane magnetization material having a perpendicular magnetic anisotropy sufficiently effective for J_{c0} reduction, Hk_{⊥} of the first ferromagnetic layer is configured to satisfy 2πMₛ<H_{k⊥}<4πMₛ.

### Advantageous Effects of Invention

By employing the recording layer configuration of the present invention, it becomes possible to prepare an in-plane magnetized MTJ device that exhibits a low writing current density while maintaining a high TMR ratio and the thermal stability.

### BRIEF DESCRIPTION OF DRAWINGS

FIG. 1 is a schematic diagram of a cross-section showing one example of an MTJ element according to the present invention.

FIG. 2 is a schematic diagram of a cross-section showing one example of the MTJ element according to the present invention.

FIG. 3 is a schematic diagram of a cross-section shows one example of the MTJ element according to the present invention.

FIG. 4 is a schematic diagram of a cross-section showing an exemplary configuration of a magnetic memory cell.

FIG. 5 is a schematic diagram showing an exemplary configuration of the random access memory.

### DESCRIPTION OF EMBODIMENTS

Hereafter, embodiments of the present invention will be explained in detail with reference to the drawing.

### Embodiment 1

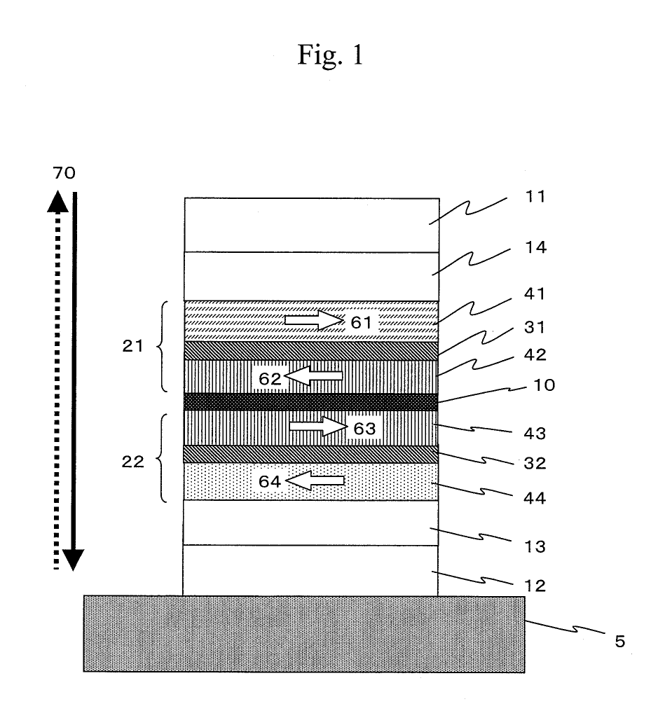

FIG. 1 shows a schematic diagram of a cross-section of an MTJ element in embodiment 1. On the Si substrate 5 on which a thermally oxidized film is formed, thin layers are laminated in the order of a lower electrode 12, an antiferromagnetic layer 13, a pinned layer 22, a barrier layer 10, a recording layer 21, a capping layer 14, and an upper electrode 11. The recording layer 21 has a synthetic ferri-magnetic structure comprising a first ferromagnetic layer 41, a second ferromagnetic layer 42 and a first non-magnetic layer 31, and the magnetization 61 of the first ferromagnetic layer 41 and the magnetization 62 of the second ferromagnetic layer 42 are coupled in an antiparallel manner (antiferromagnetic coupling). Similarly, the pinned layer 22 has a synthetic ferri-magnetic structure comprising a third ferromagnetic layer 43, a fourth ferromagnetic layer 44 and a second non-magnetic layer 32, and the magnetization 63 of the third ferromagnetic layer 43 and the magnetization 64 of the fourth ferromagnetic layer 44 are coupled in an antiparallel manner. For barrier layer 10, MgO (film thickness: 1 nm) is used. Of ferromagnetic layers constituting the recording layer 21, CoFeB (film thickness: 2.4 nm) is employed for a second ferromagnetic layer 42 being in contact with the barrier layer 10, and a first ferromagnetic layer 41 formed on the first non-magnetic layer 31 (Ru, film thickness: 0.8 nm) is constituted with a m-D0₁₉ type Co₇₅Pt₂₅ ordered alloy (film thickness: 2 nm). Further, CoFeB (film thickness: 2.5 nm) is used for a third ferromagnetic layer 43 constituting the pinned layer 22, and CoFe (film thickness: 3 nm) is used for a fourth ferromagnetic layer 44 and Ru (film thickness: 0.8 nm) is used in the second non-magnetic layer 32. MnIr (film thickness: 8 nm) is used for an antiferromagnetic layer 13. The lower electrode 12 is constituted by a laminated layer in which layers are laminated in the order of Ta (5 nm)/Ru (10 nm)/Ta (5 nm)NiFe (3 nm) from the substrate side. Further, the capping layer 14 is constituted by the laminated layer of Ta (film thickness: 5 nm)/Ru (film thickness: 10 nm).

Each layer stated above is formed on the Si substrate 5 by using an RF sputtering method using Ar gas. After the formation of the laminated layer, the element is processed into a pillar shape in which the dimension of the top face thereof is 100 nm×200 nm by using electron beam (EB) lithography and ion beam etching. Thereafter, upper electrode 11 having a laminated structure of Cr (film thickness: 5 nm)/Au (film thickness: 100 nm) is formed. Although not illustrated, to each of the upper electrode layer 11 and the lower electrode layer 12, wiring for flowing a current to the element is connected. After the element is prepared, annealing at 300° C. is performed.

The operation of the element will be described. When the current 70 flows to the MTJ element, the magnetization 61 and the magnetization 62 in the recording layer 21 are reversed according to the current direction. In this process, the magnetization 62 of the second ferromagnetic layer 42 and the magnetization 61 of the first ferromagnetic layer 41 retain a mutually antiparallel coupling. On the other hand, the magnetization 63 and the magnetization 64 in the pinned layer 22 are not reversed since the directions thereof are pinned by the antiferromagnetic layer 13. When the magnetization 62 of the second ferromagnetic layer 42 and the magnetization 63 of the third ferromagnetic layer 43, which are opposed to each other on both sides of the barrier layer 10, are aligned in parallel with each other, the element is in a low resistance state. Contrarily, when in the antiparallel alignment, the element is in a high-resistance state. Since the second ferromagnetic layer 42 being in the interface on the barrier layer 10 and affecting the TMR ratio and the third ferromagnetic layer 43 are CoFeB, a high TMR ratio of 100% or greater is obtained.

Although Co₇₅Pt₂₅ of the first ferromagnetic layer 41 is, by nature, a material that exhibits perpendicular magnetization, the strength of the perpendicular magnetic anisotropy depends on the crystalline structure and the orientation of the foundation layer. For example, when Ru of film thickness 20 nm or so is used for the foundation layer, the element exhibits a high perpendicular magnetic anisotropy 10⁷ erg/cm³ or greater. However, with an amorphous or a bcc-structured material, or a material that is of Ru but whose film thickness is thin, adequate orientation cannot be obtained, and the perpendicular magnetic anisotropy reduces. As a result, the magnetization falls in the in-plane direction. In the present embodiment, Ru of the foundation layer is as thin as 0.8 nm. Therefore, Co₇₅Pt₂₅ of the first ferromagnetic layer 41 formed thereon is an in-plane magnetization film. In the configuration of the present embodiment, saturation magnetization Mₛ of Co₇₅Pt₂₅ of the first ferromagnetic layer 41 is 1000 emu/cm³, anisotropy field H in the perpendicular direction is 10 kOe. That is, demagnetizing field in the perpendicular direction is H_{d}(=4πMₛ=12.6 kOe)>H_{k⊥}(10 kOe), and it becomes a film whose magnetic easy axis is in the in-plane direction.

As stated above, although the first ferromagnetic layer 41 is an in-plane magnetization film, it has a high anisotropy field (H_{k⊥}=10 kOe) in the perpendicular direction. Therefore, the effective demagnetizing field H_{eff} in the direction perpendicular to the film surface shown in Formula (1), Formula (2) reduces. As a result, writing current density J_{c0} can be reduced. In conventional configurations, for first ferromagnetic layer 41, CoFeB has been used. In comparison with the MTJ element of the conventional configuration, in the MTJ element of the present embodiment, J_{c0} is reduced to approximately ⅓. Further, the second magnetic layer 42 being in contact with MgO barrier layer 10 is, in the same way as conventional structure, CoFeB. Therefore, a high TMR ratio of 100% or greater is confirmed. Further, since Mₛ·t (Ms: saturation magnetization, t: film thickness) of the first ferromagnetic layer 41 is equivalent to conventional CoFeB layers, a value of thermal stability E/k_{B}T equivalent to the conventional configurations can be realized.

In embodiment 1, Co₇₅Pt₂₅ is used as a material of the first ferromagnetic layer 41. However, the same effects can be obtained when a different material with a strong perpendicular magnetic anisotropy is employed. As a specific material, an ordered alloy including any of Co, Fe, Ni, or one or more of the elements, and one or more elements of Pt, Pd, an alloy including Co and further including one or more elements of Cr, Ta, Nb, V, W, Hf, Ti, Zr, Pt, Pd, Fe, Ni, a L1₀ type ordered alloy including Co₅₀Pt₅₀, Fe₅₀Pt₅₀, Fe₅₀Pd50, a material of a granular structure in which particulate magnetic materials including CoCrPt—SiO₂, FePt—SiO₂ are dispersed in a parent phase of a non-magnetic material, or an alloy including any of Fe, Co, Ni or one or more of them, a laminated layer in which non-magnetic metals including Ru, Pt, Rh, Pd, Cr are alternately laminated, or, a laminated layer in which Co and Ni are alternately laminated, or, TbFeCo, GdFeCo that are amorphous alloys containing transition metals in rare earth metals including Gd, Dy, Tb, may be used.

On employment of these materials, perpendicular magnetic anisotropy of the film is controlled according to formation conditions so that 4πMₛ>H_{k⊥}, is achieved. L1₀ ordered alloys, for example, can control perpendicular magnetic anisotropy by adjustment of film formation temperature. For these ordered alloys, crystalline orientation is important in order to realize perpendicular magnetization. If the crystalline orientation is insufficient, the magnetic easy axis is in the in-plane direction (H_{k⊥}<4πMₛ). In order to form an ordered phase, in general, a formation temperature of 500° C. or greater is needed. Therefore, conversely, by lowering the formation temperature to be less than 500° C., the perpendicular magnetic anisotropy can be reduced so that 4πMₛ>H_{k⊥} is achieved. Further, with multilayer film comprising a Co/Pt, Co/Pd, CoFe/Pd, perpendicular magnetic anisotropy can be controlled by adjusting the film thickness of each layer and the lamination cycle. In the case of such a multilayer film, it is known that, for example, perpendicular magnetic anisotropy decreases when the film thickness of the ferromagnetic layer is increased, and the multilayer film becomes an in-plane magnetization material. As one example of the in-plane magnetization magnetic layer having the perpendicular magnetic anisotropy, desirable configurations may include [Co (1 nm)/Pd (1.5 nm)]×3 cycles. Also in the case of using such a material, the same effects as embodiment 1 can be obtained. Further, where CoFeB is used as the first ferromagnetic layer 41, in order to make the layer to be an in-plane magnetization film, it is preferable that the film thickness is made 1.5 nm or greater and 2 nm or less.

Further, although in embodiment 1, CoFeB is used for the second ferromagnetic layer, of course, same effects can be obtained also when other materials having a bcc crystalline structure, for example, CoFe or Fe, are used.

### Embodiment 2

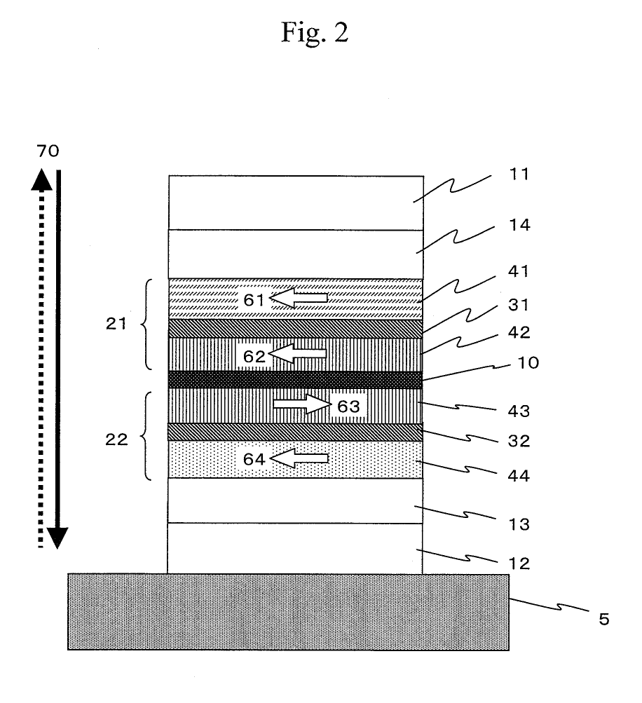

Embodiment 2 proposes an MTJ element in which the recording layer has a synthetic ferro-magnetic structure of a ferromagnetic coupling. The schematic diagram of a cross-section of the element is shown in FIG. 2. Except for the first non-magnetic layer 31, the material and film thickness of each layer is the same as embodiment 1.

In embodiment 2, Ru of film thickness of 1.5 nm is used for the first non-magnetic layer 31. The coupling direction of the two ferromagnetic layers in the synthetic ferro-magnetic structure depends on the film thickness of the non-magnetic layer inserted therebetween. In the case of Ru of film thickness (1.5 nm) in embodiment 2, the magnetization 61 and the magnetization 62 of the first ferromagnetic layer 41 and the second ferromagnetic layer 42 are coupled with each other in the parallel direction (ferromagnetic coupling).

Except for the two magnetic layers 41, 42 in the recording layer 21 undergo magnetization reversal while being coupled with each other in the parallel direction, the operation of the MTJ element is the same as embodiment 1. Further, also regarding the writing current density J_{c0} reduction effect equivalent to embodiment 1 is confirmed. Further, since the second magnetic layer 42 being in contact with MgO barrier layer 10 is, in the same way as conventional structure, CoFeB, a high TMR ratio of 100% or greater is confirmed. On the other hand, an effect is confirmed in which the thermal stability E/k_{B}T increases approximately 1.5 times larger than the element of embodiment 1. This is due to an effect of the magnetic coupling direction in the synthetic ferro-magnetic structure. In embodiment 1, the two magnetic layers are coupled in an antiferromagnetic manner, the in-plane demagnetizing field in each layer is insulated by a magnetostatic coupling field (magnetic pole is unlikely to be generated). Therefore, shape magnetic anisotropy is suppressed and the energy of the magnetic material is reduced. As compared to this, where the magnetic layer in the synthetic ferro-magnetic structure is coupled in a ferromagnetic manner as in embodiment 2, since there is no reduction in the shape magnetic anisotropy (there is no screening effect of the demagnetizing field), the energy of the magnetic material is high, and the thermal stability E/k_{B}T is large as compared to embodiment 1.

### Embodiment 3

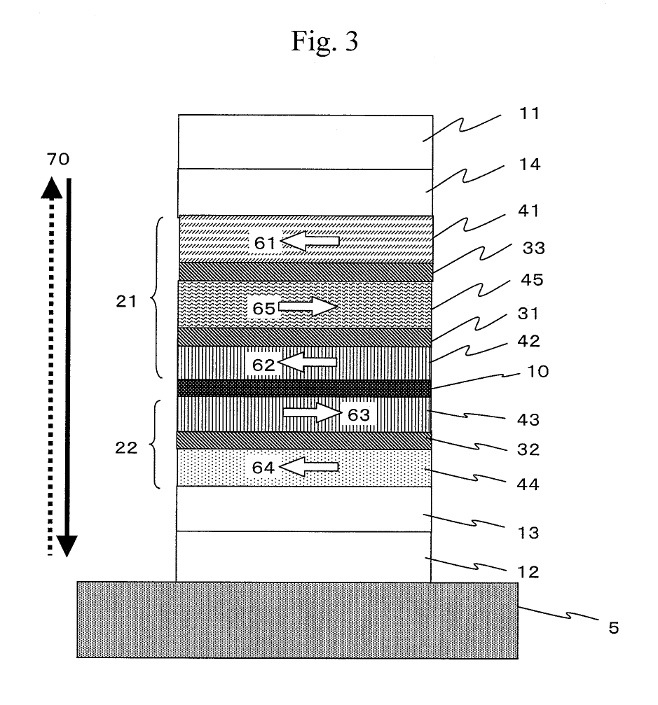

Embodiment 3 proposes an MTJ element in which thin CoFeB is employed as the material of the recording layer. A schematic diagram of a cross-section of the element is shown in FIG. 3. The material and film thickness of each layer is the same as embodiment 1 except for the material and the configuration of the recording layer.

In embodiment 3, the recording layer 21 is formed of a laminated configuration including a second ferromagnetic layer 42/a first non-magnetic layer 31/a fifth ferromagnetic layer 45/a third non-magnetic layer 33/a first ferromagnetic layer 41. The material of the first ferromagnetic layer 41, the second ferromagnetic layer 42 and the fifth ferromagnetic layer 45 is CoFeB of a film thickness of 1.5 nm, and Ru is employed for the first non-magnetic layer 31 and the third non-magnetic layer 33. In general, in an in-plane magnetized MTJ device, CoFeB whose film thickness is 2 nm or greater is used for the recording layer. CoFeB has a characteristic of increasing a perpendicular magnetic anisotropy when the layer is thinned. In the present embodiment, with CoFeB of a film thickness of 1.5 nm, saturation magnetization Mₛ=1100 emu/cm³, anisotropy field Hk_{⊥}=8 kOe in the perpendicular direction are confirmed. By using CoFeB of this film thickness, a recording layer of a laminated structure of CoFeB (1.5)/Ru (0.8)/CoFeB (1.5)/Ru (0.8)/CoFeB (1.5) is constituted. By this structure of the MTJ element, writing current density J_{c0} is reduced to approximately half as compared to an MTJ element having a recording layer of CoFeB (2)/Ru (0.8) /CoFeB (2). Further, regarding the TMR ratio, since a ferromagnetic layer CoFeB that is the same as conventional ones is used, a value of 100% or greater is confirmed. Further, since the volume of the ferromagnetic material that constitutes the recording layer is made equal to conventional configurations, a value that is same as the conventional configuration can be obtained also for E/k_{B}T.

In the present embodiment, CoFeB of the recording layers is coupled with each other in an antiferromagnetic manner via Ru, and magnetization of adjacent CoFeB layers is aligned in an antiparallel manner From this, the same effects can be obtained also when Ru film thickness is adjusted as in embodiment 2 (for example 1.5 nm) so as to be coupled in a ferromagnetic manner such that magnetization of each of both adjacent layers is aligned in the same direction. In this case, since the shape magnetic anisotropy is not reduced (there is no screening effect of the demagnetizing field), the energy of the magnetic material is high and the thermal stability E/k_{B}T increases as compared to the configuration of embodiment 3.

### Embodiment 4

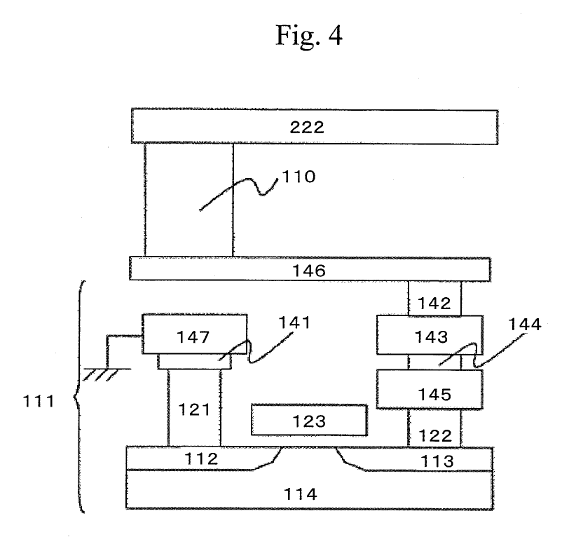

Embodiment 4 proposes a random access memory for which the MTJ element according to the present invention is employed. FIG. 4 shows a schematic diagram of a cross-section of an exemplary configuration of a magnetic memory cell according to the present invention. On this magnetic memory cell, an MTJ element 110 as shown in embodiment 1-3 is mounted.

The C-MOS 111 comprises two n-type semiconductors 112, 113 and one p-type semiconductor 114. The electrode 121 to serve as the drain is electrically connected to the n-type semiconductor 112, and connected to the ground via the electrode 141 and the electrode 147. To the n-type semiconductor 113, an electrode 122 to serve as the source is electrically connected. Further, reference numeral 123 denotes a gate electrode, and by turning ON/OFF of the gate electrode 123, ON/OFF state of the current between the source electrode 122 and the drain electrode 121 is controlled. An electrode 145, an electrode 144, an electrode 143, an electrode 142 and an electrode 146 are laminated on the source electrode 122, and the lower electrode 12 of the MTJ element 110 is connected via the electrode 146.

A bit line 222 is connected to the upper electrode 11 of the MTJ element 110. In the magnetic memory cell of the present embodiment, a current flowing to the MTJ element 110, in other words, the spin-transfer torque, revolves the magnetization direction of the recording layer of the MTJ element 110 to record the magnetic information. The spin transfer torque is not a spatial external magnetic field, but a principle in which mainly the spin of a spin polarized current flowing through the MTJ element provides a torque to magnetic moment of the ferromagnetic recording layer of the tunneling magnetoresistive effect device. Therefore, by having means for externally supplying a current to the MTJ element, and flowing the current by using the means, spin transfer torque magnetization reversal is realized. In the present embodiment, by flowing a current between a bit line 222 and an electrode 146, the magnetization direction of the recording layer in the MTJ element 110 is controlled.

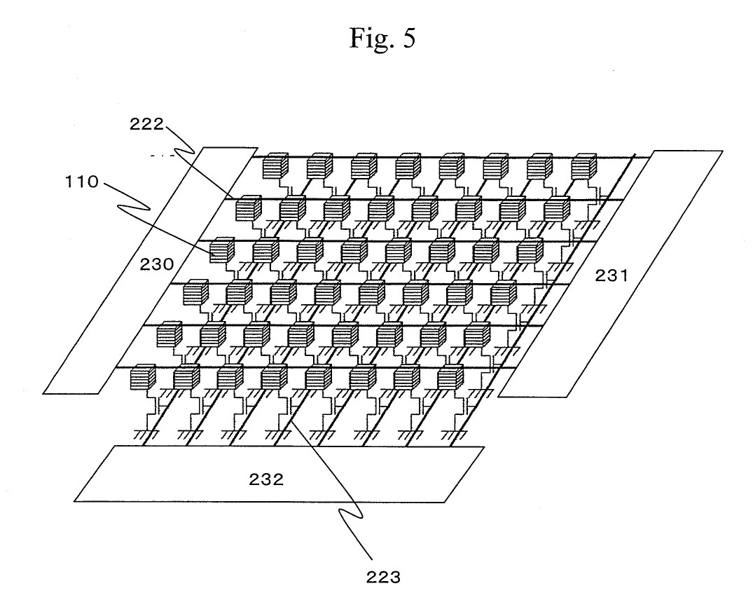

FIG. 5 is a diagram showing an exemplary configuration of the magnetic random access memory in which the above-described magnetic memory cell is disposed. A word line 223 connected to the gate electrode 123 and a bit line 222 are electrically connected to the magnetic memory cell. By disposing the magnetic memory cell comprising the MTJ element described in embodiments 1 to 3, the magnetic memory can operate with low power consumption as compared to conventional configurations, and it is possible to realize a highly dense magnetic memory of gigabit class.

Writing in the present configuration comprises, first, sending a write enable signal to a writing driver connected to the bit line 222 to which a current is intended to flow to raise voltage, and flowing a predetermined current to the bit line 222. In accordance with the direction of the current, either one of the writing driver 230 or the writing driver 231 is connected to the ground, to adjust the electric potential difference and control the current direction. Next, after elapse of a predetermined time, a write enable signal is sent to the writing driver 232 connected to the word line 223, to raise the voltage of the writing driver 232 to turn on the transistor connected to an MTJ element to which writing is intended to be performed. Accordingly, a current flows to the MTJ element 110, and spin torque magnetization reversal is performed. After placing the transistor to be in the on-state for a predetermined time, the signal to the writing driver 232 is disconnected and the transistor is turned off. Upon readout, the voltage is raised to the readout voltage V only in the bit line 222 connected to an MTJ element on which readout is intended to be performed, selection transistor is turned on and the current flows. Readout is performed in this way. Since this structure is composed of the most simple arrangement, comprising 1 transistor+1 memory cell, the area which unit cell occupies can be as highly integrated as 2F×4F=8F².

### REFERENCE SIGNS LIST

5 . . . substrate, 10 . . . barrier layer, 11 . . . upper electrode , 12 . . . lower electrode, 13 . . . antiferromagnetic layer, 14 . . . capping layer, 21 . . . recording layer, 22 . . . pinned layer, 31 . . . first non-magnetic layer, 32 . . . second non-magnetic layer, 33 . . . third non-magnetic layer, 41 . . . first ferromagnetic layer, 42 . . . second ferromagnetic layer, 43 . . . third ferromagnetic layer, 44 . . . fourth ferromagnetic layer, 61, 62, 63, 64, 65 . . . magnetization, current . . . 70, 110 . . . MTJ element, 111 . . . l C-MOS, 112, 113 . . . n-type semiconductor, 114 . . . p- type semiconductor, 121 . . . source electrode, 122 . . . drain electrode, 123 . . . gate electrode, 141, 142, 143, 144, 145, 146, 147 . . . electrode, 150 . . . writing line, 222 . . . bit line, 223 . . . word line, 230, 231, 232 . . . writing driver

1. A tunneling magnetoresistive effect device comprising:
a recording layer comprising a ferromagnetic material thin film;
a pinned layer comprising a ferromagnetic material thin film in which a magnetization direction is pinned in one direction; and
a barrier layer of MgO disposed between the recording layer and the pinned layer;
wherein the recording layer is a laminated thin film in which a non-magnetic layer is disposed between a first ferromagnetic layer and a second ferromagnetic layer,
the second ferromagnetic layer is disposed to be in contact with the barrier layer, and
the first ferromagnetic layer comprises a material that satisfies a relationship of 2πMₛ<H_{k⊥}<4πMₛ when the saturation magnetization is Mₛ (emu/cm³) and the perpendicular magnetic anisotropy field is H_{k⊥} (Oe).

2. The tunneling magnetoresistive effect device according to claim 1, wherein magnetization of the first ferromagnetic layer and magnetization of the second ferromagnetic layer are coupled to be in antiparallel with each other.

3. The tunneling magnetoresistive effect device according to claim 1, wherein magnetization of the first ferromagnetic layer and magnetization of the second ferromagnetic layer are coupled to be in parallel with each other.

4. The tunneling magnetoresistive effect device according to claim 1, wherein the second ferromagnetic layer is CoFeB, CoFe or Fe.

5. The tunneling magnetoresistive effect device according to claim 1, wherein the material of the first ferromagnetic layer is an ordered alloy including any of Co, Fe, Ni, or one or more elements thereof, and one or more elements of Pt and Pd.

6. The tunneling magnetoresistive effect device according to claim 1, wherein a material of the first ferromagnetic layer comprises Co, and is an alloy comprising one or more elements of Cr, Ta, Nb, V, W, Hf, Ti, Zr, Pt, Pd, Fe and Ni.

7. The tunneling magnetoresistive effect device according to claim 1, wherein a material of the first ferromagnetic layer is a laminated film in which any one of Fe, Co, Ni, or an alloy comprising one or more elements thereof, and any of a non-magnetic metal of Ru, Pt, Rh, Pd, Cr are alternately laminated.

8. The tunneling magnetoresistive effect device according to claim 1, wherein a material of the first ferromagnetic layer is a material of a granular structure in which a periphery of particulate magnetic phase is surrounded by a non-magnetic phase.

9. The tunneling magnetoresistive effect device according to claim 1, wherein the material of the first ferromagnetic layer is an amorphous alloy comprising a rare earth metal and a transition metal.

10. The tunneling magnetoresistive effect device according to claim 1, wherein a material of the first ferromagnetic layer is CoFeB whose film thickness is 1.5 nm or greater and 2 nm or less.

11. The tunneling magnetoresistive effect device according to claim 1, wherein a material of the first ferromagnetic layer is a laminated film in which Co and Ni are alternately laminated.

12. A random access memory comprising a plurality of magnetic memory cells and means for selecting a desired magnetic memory cell from the plurality of magnetic memory cells, wherein
the magnetic memory cell comprises a tunneling magnetoresistive effect device and a transistor serially-connected to the tunneling magnetoresistive effect device,
a side of the tunneling magnetoresistive effect device that is not connected to the transistor is connected to a bit line connected to a first writing driver circuit,
a gate electrode of the transistor is connected to a word line connected to a second writing driver circuit,
the tunneling magnetoresistive effect device comprises a recording layer comprising a ferromagnetic material thin film, a pinned layer that comprises a ferromagnetic material thin film and whose magnetization direction is pinned in one direction, and a barrier layer of MgO disposed between the recording layer and the pinned layer, the recording layer is a laminated thin film in which a non-magnetic layer is disposed between the first ferromagnetic layer and the second ferromagnetic layer, the second ferromagnetic layer is disposed to be in contact with the barrier layer, and the first ferromagnetic layer comprises a material that satisfies a relationship of 2πMₛ<H_{k⊥}<4πMₛ when the saturation magnetization is Mₛ (emu/cm³) and the perpendicular magnetic anisotropy field is H_{k⊥}(Oe), and writing of information is performed by causing magnetization reversal of the recording layer of the magnetic memory cell by a spin transfer torque induced by a current flowing through the transistor.
